(19) United States
(12) Patent Application Publication
(10) Pub. No.: US 2008/0128874 A1
(43) Pub. Date: Jun. 5, 2008

(54) Semiconductor device

(75) Inventor: Akira Haga, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/987,768

(22) Filed: Dec. 4, 2007

(30) Foreign Application Priority Data
Dec. 5, 2006 (JP) 2006-327791

(51) Int. Cl. H01L 23/538

(52) U.S. Cl. 257/665; 257/E21.169

(57) ABSTRACT

A semiconductor device includes a first semiconductor chip having first pads arranged at first interval, a second semiconductor chip having second pads arranged at second interval, the second interval being larger than the first interval and a relay substrate arranged between the first semiconductor chip and the second semiconductor chip, the relay substrate having first relay pads and second relay pads, the first relay pads arranged at first interval being formed along a side facing the first semiconductor chip and the second relay pads arranged at second interval being formed along a side facing the second semiconductor chip, in which the first semiconductor chip and the second semiconductor chip are connected to each other through the relay substrate.

### BACKGROUND OF THE INVENTION

1. Field of the Invention

The present invention relates to a semiconductor device having a relay substrate connecting semiconductor chips mounted on an SiP (System in Package) where several chips are packaged together.

2. Description of Related Art

Semiconductor units such as semiconductor chips mounted on a substrate are becoming increasingly highly densified and the semiconductor device has been increasingly miniaturized and thinned. Such a semiconductor device includes an SiP, for example. In the SiP, semiconductor device is packaged in substantially a chip size. The SiP is manufactured by forming semiconductor chips having different functions on a single substrate and packaging the semiconductor chips. In the SiP, signal is transmitted and received between the semiconductor chips mounted on the SiP, and desired signal is transmitted to external part of the SiP.

A semiconductor system employing such an SiP is disclosed in Japanese Unexamined Patent Application Publication No. 11-86546 (Takemae). In the semiconductor system disclosed in Takemae, pads disposed on the semiconductor chips in the SiP are connected to each other by bonding wires. However, in the semiconductor device disclosed in Takemae, the semiconductor chips are directly connected to each other by the bonding wires. Therefore, a problem occurs that the signal transmitted and received through the bonding wires are easily affected by noise.

Another semiconductor device which connects the semiconductor chips through a relay substrate instead of directly connecting the semiconductor chips is disclosed in Japanese Unexamined Patent Application Publication No. 8-203921 (Kawakami), No. 2-27758 (Itou), and No. 2001-267493 (Inoue). In the semiconductor device disclosed in Kawakami, the two semiconductor chips (power element) are connected in parallel through the relay substrate. This structure is different from the semiconductor device disclosed in Takemae in that there is a purpose of performing a parallel behavior at a time in the semiconductor device disclosed in Kawakami. Therefore, the semiconductor device disclosed in Kawakami does not transmit and receive the signal between the semiconductor chips (power element). Further, a current detecting element is provided only in a main semiconductor chip (main power element), and three terminals, the current detecting terminal, and a gate control electrode and a source control electrode that are common to both semiconductor chips (power element), are connected by a wiring in the relay substrate and those three terminals are connected to the exterior. Therefore, in the semiconductor device disclosed in Kawakami, three wirings are made to approach to minimize influence of peripheral magnetic field, to thereby improving an accuracy of current detection. Therefore, unlike the technique in Takemae, noise of the signal transmitted and received between the semiconductor chips is not a problem.

On the other hand, a semiconductor device having semiconductor chips connected to one another through a relay substrate is disclosed in Itou and Inoue. In the semiconductor device disclosed in Itou, a first IC chip and a second IC chip are faced with each other. Then a third IC chip is faced to the first IC chip and the second IC chip. In summary, the first IC chip and the second IC chip are arranged in parallel along with one side of the third IC chip. The relay substrate is formed between the first and second IC chips and the third IC chip. Each IC chip is connected to one another through the relay substrate by connecting each of the pads formed on the first IC chip, the pads formed on the second IC chip, and the pads formed on the third IC chip to the relay substrate.

A semiconductor device disclosed in Inoue is shown in FIG. 4. The semiconductor device shown in FIG. 4 has chips 92 to 95 arranged on a support substrate 91. A plurality of input and output terminals 92a are arranged on the chip 92, a plurality of input and output terminals 93a are arranged on the chip 93, and a plurality of input and output terminals 94a are arranged on the chip 94. A plurality of input and output terminals 95a and 95b are arranged on the chip 95. The input and output terminals 92a arranged on the chip 92 are connected to the input and output terminals 91a arranged on the support substrate 91 by a wiring 96. The input and output terminals 93a formed on the chip 93 are connected to the input and output terminals 91a by a wiring 97. The input and output terminals 94a formed on the chip 94 are connected to the input and output terminals 91a by a wiring 98. The chip 92 and the chip 93 are connected to each other through the chip 95. Therefore, the input and output terminals 92a and the input and output terminals 95a of the chip 95 are connected to each other through a wiring 99. The input and output terminals 93a and the input and output terminals 95b of the chip 95 are connected to each other through a wiring 100. Further, the chip 93 and the chip 94 are connected to each other through a wiring 101. The chip 95 is composed of a plurality of wiring layers. Therefore, the input and output terminals 95a and the input and output terminals 95b are connected to each other in the chip 95. Therefore, the chip 92 and the chip 93 are connected to each other through the chip 95.

However, in the related semiconductor devices disclosed in Itou and Inoue, distance between pads formed on each of the semiconductor chips (hereinafter referred to as pad pitch) is assumed to be constant. Therefore, it is not assumed that the pad pitch is different for each semiconductor chip. There has recently been an increasing demand from the user that the pads of the semiconductor chips having different pad pitches be connected to each other. The case in which the pad pitches are different will now be described.

A manufacturing process and an assembly technique of the semiconductor device have recently made a remarkable progress, and a new semiconductor chip is developed in a year or two. Therefore, there is a demand that a newly developed semiconductor chip and a related semiconductor chip be mounted on a single semiconductor device. In other words, there is a demand that the semiconductor chips having different generations be mounted on the single semiconductor device. For example, it includes a case in which a latest central processing unit (CPU) and an old gate array which is used for two or three generations ago or the like need to be mounted on the single semiconductor device. The latest CPU is designed and manufactured by a latest manufacturing process so as to be able to perform high-speed operation. On the other hand, the gate array is manufactured by a manufacturing process which has been employed for a certain period of time. In such a case, pad pitches of pads formed on the semiconductor chips can be different. Moreover, by newly designing and developing all of the chips mounted on the semiconductor device, TAT (Turn Around Time), which is the time needed for performing a series of process for development of the chip, can be long. To shorten the TAT, only the chip of which the function is desired to be changed may be designed and manufactured. Therefore, the chips having different pad pitches can be mounted on the single semiconductor device.

Because the pad pitches are different for each semiconductor chip, the number of pads formed in the sides where the semiconductor chips face to each other is different. However, in the related relay substrate, the case in which the pad pitches of the semiconductor chips are different is not assumed. In the related relay substrate, the pads formed in the relay substrate are formed at a fixed interval in any pad pitch of the semiconductor chip. Therefore, there has been a problem that some pads formed on each semiconductor chip and connecting the semiconductor chips through the relay substrate are not connected to the relay substrate and the some pads are remained unconnected. The semiconductor device disclosed in Kawakami does not transmit and receive the signal between the semiconductor chips by interposing the relay substrate between the semiconductor chips when connection is made between the semiconductor chips having different pad pitches.

### SUMMARY

In one embodiment of the present invention, a semiconductor device includes a first semiconductor chip having first pads arranged at first interval, a second semiconductor chip having second pads arranged at second interval, second interval being larger than the first interval and a relay substrate arranged between the first semiconductor chip and the second semiconductor chip, the relay substrate having a first relay pad and a second relay pad, the first relay pad arranged at first interval being formed along a side facing the first semiconductor chip and the second relay pad arranged at second interval being formed along a side facing the second semiconductor chip, in which the first semiconductor chip and the second semiconductor chip are connected to each other through the relay substrate.

In one embodiment of the present invention, when the pad pitches of the first pads formed at first interval on the first semiconductor chip and the second pads performed at second interval on the second semiconductor chip are different, the relay substrate having pads in accordance with the intervals of each pad is used, to thereby connecting the first semiconductor chip and the second semiconductor chip to each other.

According to the embodiment of the present invention, a connection between chips, each of chips having a different pad pitches, can be easily achieved.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 shows a perspective view of an SiP according to the present embodiment;

FIG. 2 shows a structure of a relay substrate according to the present embodiment;

FIG. 3 shows a perspective view showing the relay substrate having a chip capacitor mounted thereon; and

FIG. 4 shows a part of a plan view of a semiconductor system according to a related art.

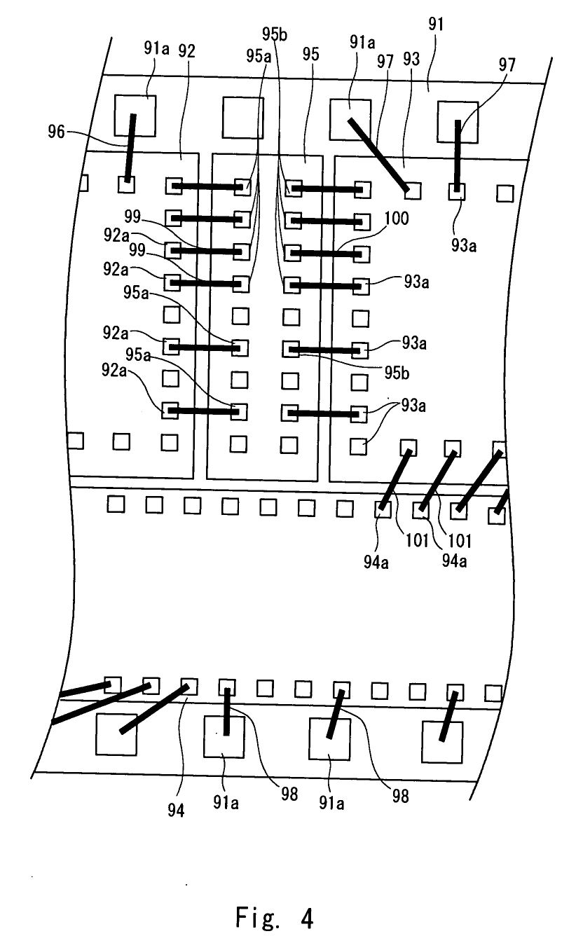

### DETAILED DESCRIPTION OF PREFERRED EMBODIMENTS

The invention will now be described herein with reference to illustrative embodiments. Those skilled in the art will recognize that many alternative embodiments can be accomplished using the teachings of the present invention and that the invention is not limited to the embodiments illustrated for explanatory purposes.

### Embodiment 1

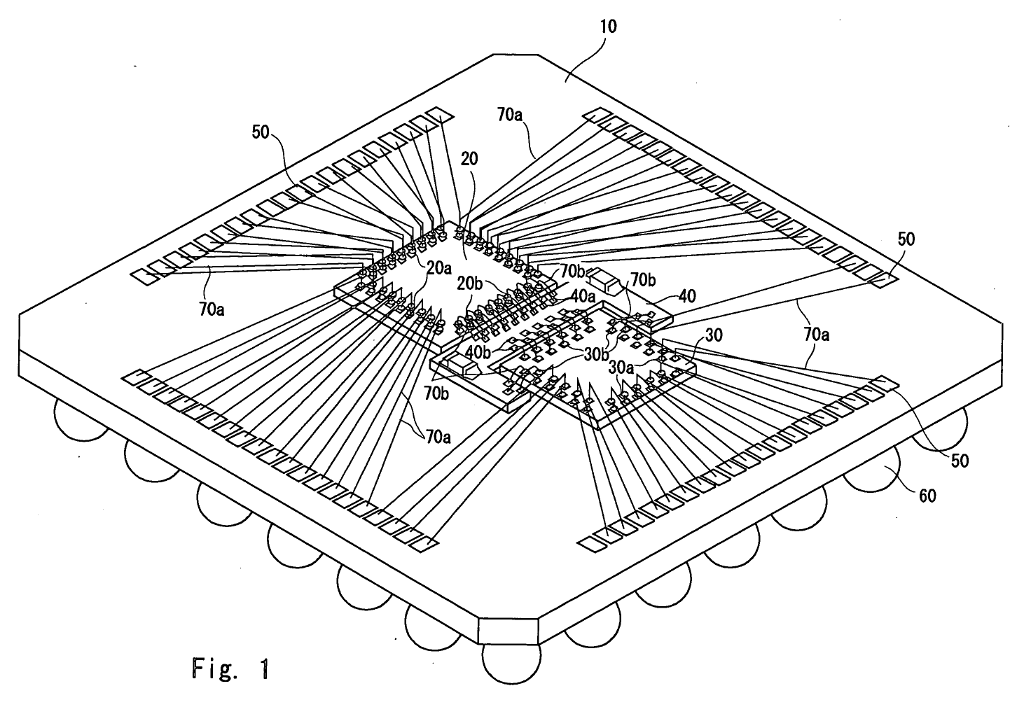

The present embodiment will now be described in detail with reference to FIG. 1. The present embodiment is the one in which the present invention is applied to an SiP. FIG. 1 shows a perspective view of the SiP according to the present embodiment. As shown in FIG. 1, the SiP in this embodiment includes a first semiconductor chip (hereinafter referred to as first chip) 20, a second semiconductor chip (hereinafter referred to as second chip) 30, a relay substrate 40 composed of a plurality of wiring layers, and peripheral pads 50 on a substrate 10 composed of a plurality of layers. Note that a chip mounting substrate (not shown) connected to ground or power supply may be formed between the first chip 20 and/or the second chip 30 and the substrate 10.

The substrate 10 is a PBGA (Plastic Ball Grid Array) substrate, for example, and has solder balls 60 formed on a rear surface. The first chip 20 has a plurality of first connecting pads 20a. In the present embodiment, the first connecting pads 20a are formed in two arrays in a zigzag pattern, for example. The first connecting pads 20a that are connected to second connecting pads 30b through the relay substrate 40 are called first connecting pads 20b. The second connecting pads 30b will be described below. In the present embodiment, the first connecting pads 20b are formed along a side in which the first chip 20 and the second chip 30 are faced to each other (hereinafter referred to as facing side). The second chip 30 has a plurality of second connecting pads 30a. In the present embodiment, the second connecting pads 30a are formed in two arrays in the zigzag pattern. The second connecting pads 30b that are connected to the first connecting pads 20a through the relay substrate 40 are called second connecting pads 30b.

The relay substrate 40 has first relay pads 40a connected to the first connecting pads 20b and second relay pads 40b connected to the second connecting pads 30b. The relay substrate 40 is horseshoe-shaped, for example. Note that the horseshoe shape includes U shape. The relay substrate 40 that is horseshoe-shaped is arranged between the first chip 20 and the second chip 30 so as to surround the second chip 30. In the present embodiment, the pad pitch of the first connecting pads 20a and 20b formed on the first chip 20 and the pad pitch of the second connecting pads 30a and 30b formed on the second chip 30 are different from each other. More specifically, the pad pitch of the first connecting pads 20a and 20b is shorter than the pad pitch of the second connecting pads 30a and 30b.

Therefore, in the present embodiment, the first relay pads 40a and the second relay pads 40b are arranged on the relay substrate 40. The first relay pads 40a correspond to the pad pitch of the first connecting pads 20b connected to the relay substrate 40 and the second relay pads 40b correspond to the pad pitch of the second connecting pads 30b connected to the relay substrate 40. The first relay pads 40a are formed along the side facing the first chip 20 and the second relay pads 40b are formed along the side facing the second chip 30. Therefore, it is possible to connect the semiconductor chips through the relay substrate 40 even when the semiconductor chips having different pad pitches are mounted on the single SiP. As stated above, there is provided the first relay pads 40a which correspond to the pad pitch of the first connecting pads 20b and the second relay pads 40b which correspond to the pad pitch of the second connecting pads 30b, which makes it possible to connect bonding wires 70b substantially perpendicular to the facing side on the plane. Therefore, it is possible to make the wiring length of the bonding wires 70b connecting the first connecting pads 20b and the first relay pads 40a substantially shortest. Moreover, it is possible to reduce noise of the signal which is transmitted and received through the bonding wires 70b.

Because the pad pitch of the connecting pads on the first chip 20 and the pad pitch of the connecting pads on the second chip 30 are different, the number of connecting pads on the first chip 20 and the number of connecting pads on the second chip 30 formed along the facing side are different. In the present embodiment, the pad pitch of the first connecting pads 20a and 20b is shorter than the pad pitch of the second connecting pads 30a and 30b. Therefore, the number of first connecting pads 20b formed along the facing side on the first chip 20 is larger than the number of second connecting pads 30a formed along the facing side on the second chip 30. Therefore, if the second connecting pads 30a formed along the facing side on the second chip 30 are called the second connecting pads 30b connected to the first connecting pads 20b, it is impossible to connect all of the first connecting pads 20b with the second connecting pads 30b formed in the facing side.

In the present embodiment, in addition to the second connecting pads 30b formed along the facing side on the second chip 30, a part of the second connecting pads 30a formed along the sides other than the facing side is called second connecting pads 30b. For example, a part of the second connecting pads 30a formed along the two sides which are adjacent to the facing side is called second connecting pads 30b connected to the relay substrate 40b. Therefore, the second connecting pads 30b are formed along three sides of the second chip 30.

Note that the relay substrate 40 in this embodiment is formed in the horseshoe shape, which means the relay substrate 40 is formed in the shape having sides facing three sides of the second chip 30. Therefore, it is possible to form the second relay pads 40b along the sides other than the facing side on the second chip 30 to connect the second relay pads 40b with the second connecting pads 30b. Therefore, it is possible to connect the first connecting pads 20b formed along the facing side on the first chip 20 with the second connecting pads 30b formed on the second chip 30 through the relay substrate 40. The first connecting pads 20b and the first relay pads 40a as well as the second connecting pads 30b and the second relay pads 40b are connected to each other by the bonding wires 70b.

Each of the first connecting pads 20a and the second connecting pads 30a is connected to the peripheral pads 50 by bonding wires 70a. The peripheral pads 50 are connected to the solder balls 60 on the substrate 10 and are transmitting and receiving pads or the like which output and input signal which is transmitted to and received from external part of SiP.

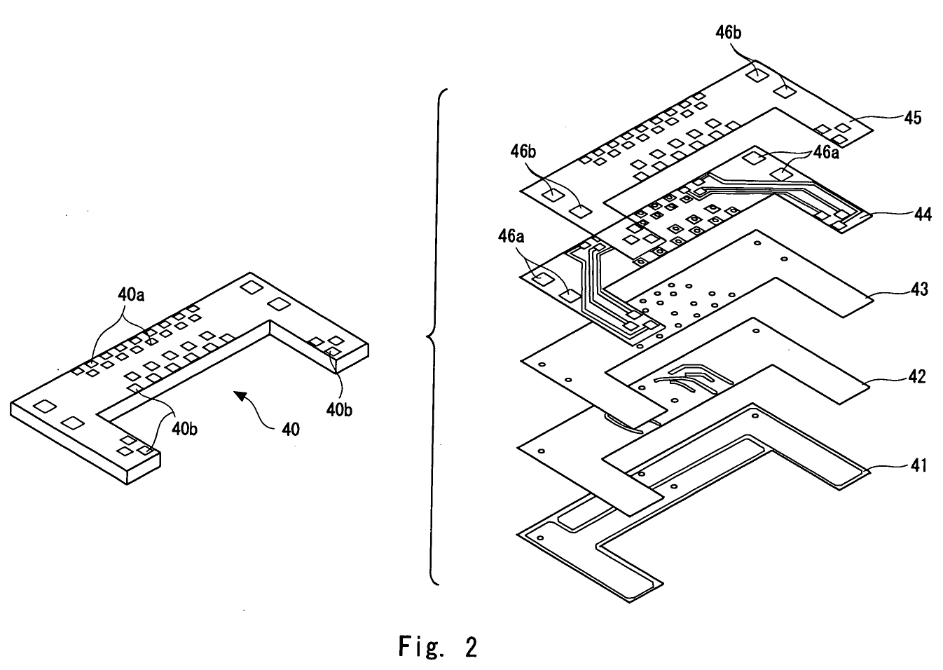

The relay substrate 40 will now further be described in detail with reference to FIG. 2. FIG. 2 shows a perspective view and an exploded perspective view of layers of the relay substrate 40. As shown in FIG. 2, the relay substrate 40 is composed of four layers, for example. A power supply layer 41 composed of power supplies supplied to the first chip 20 and to the second chip 30 is formed on the first layer. A wiring layer 42 having a wiring connecting the first connecting pads 20b and the second connecting pads 30b is formed on the second layer. A ground layer 43 supplying ground voltage to the first chip 20 and the second chip 30 is formed on the third layer. A wiring connecting the first connecting pads 20b and the second connecting pads 30b arranged along with the sides other than the facing side and pads for chip capacitors 46a which will be described below are formed on the fourth layer. A cover layer 45 having pads for chip capacitors 46b is formed on the fourth layer. The cover layer 45 has the first relay pads 40a connected to the first connecting pads 20b along with the side facing the first chip 20 and the second relay pads 40b connected to the second connecting pads 30b along with the side facing the second chip 30. These layers are formed by organic substrates, for example.

The first connecting pads 20b connected to the first relay pads 40a on the relay substrate 40 and the second connecting pads 30b connected to the second relay pads 40b on the relay substrate 40 are connected in the wiring layers 42 and 44 or the like in the relay substrate 40. For example, when the first chip 20 and the second chip 30 are connected only by bonding wires, signal transmitted and received through the bonding wires is susceptible to noise. However, in the present embodiment, the signal is transmitted and received through the relay substrate 40 having a wiring formed on the organic substrate. Therefore, it is possible to reduce the influence by noise on the signal in the wiring.

The ground layer 43 and the wiring layer 44 can be formed in microstrip line structure in accordance with speed or the like of the signal transmitted and received through the wiring layers 42 and 44 of the relay substrate 40. The ground layer 43, the wiring layer 42, and the power supply layer 41 may be formed in strip line structure. Hence, it is possible to reduce reflection noise which is occurred when the signal is transmitted and received between the ground layer 43 and the wiring layer 44 or 42. This effect is called signal integrity (SI) improvement of the wiring. It is also possible to increase the number of layers of the relay substrate 40 appropriately. For example, it may be possible to dispose an insulating layer between the wiring layers 42 and 44. When the high-speed signal is transmitted and received, it is possible to reduce noise of the signal by interposing a plurality of insulating layers between the wiring layers 42 and 44 having wiring connecting the first chip 20 and the second chip 30. In other words, it is possible to achieve the SI improvement of the wiring which connects the first chip 20 and the second chip 30. When the substrate 10 has a plurality of semiconductor chips mounted thereon, the first power supply layer 41 is separated into a plurality of power supplies so as to accord with the number of power supplies of the semiconductor chip. This structure makes it possible to constantly supply power supply voltage to each of the semiconductor chips.

Chip capacitors 46 may be mounted on the relay substrate 40 using the pads for chip capacitors 46a arranged on the wiring layer 44 and the pads for chip capacitors 46b arranged on the cover layer 45. The chip capacitors 46 are connected to the pads for chip capacitors 46b. Ground voltage is supplied from the underlying ground layer 43 to the pads for chip capacitors 46b or power supply voltage is supplied from the power supply layer 41 to the pads for chip capacitors 46b through the pads for chip capacitors 46a. The chip capacitors 46 are the elements decreasing noise of the signal transmitted and received in the semiconductor device.

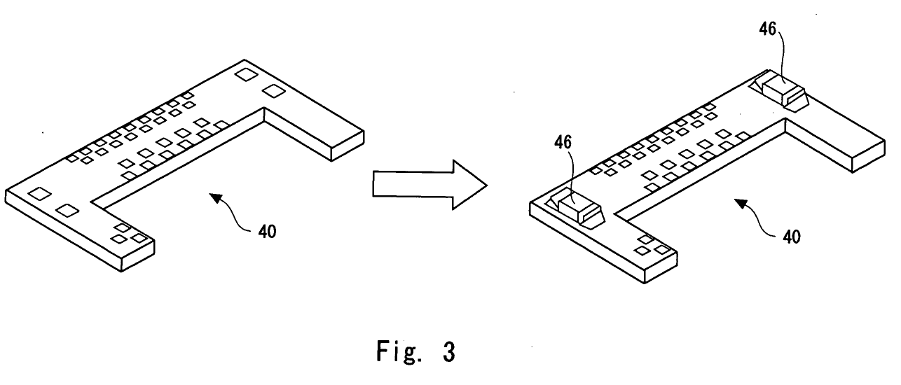

FIG. 3 shows the relay substrate 40 having the chip capacitors 46 mounted thereon. By mounting the chip capacitors 46 on the relay substrate 40, it is possible to mount the chip capacitors 46 on the relay substrate 40 in advance even when there are no devices to mount chip capacitors in an SiP assembly line. The chip capacitors 46 are mounted on the relay substrate 40 in advance to assemble an SiP device. Thereby it is possible to repair the relay substrate 40 before mounting the relay substrate 40 on the substrate 10 or to replace only the relay substrate 40 if there is something wrong with the chip capacitors 46. Therefore, it is possible to reduce rejection rate of the SiP. It is also possible to constantly supply power supply voltage and ground voltage to the first chip 20 or the like mounted on the SiP, for example. Moreover, instead of mounting the chip capacitors 46, it is possible to mount devices such as a chip resistor or a regulator or the like that controls voltage such as the first chip 20 and the second chip 30 or the like.

In the present embodiment, the pad pitch of the first connecting pads 20a and 20b formed on the first chip 20 and the pad pitch of the second connecting pads 30a and 30b formed on the second chip 30 are different from each other. The pad pitch of the first connecting pads 20a and 20b is shorter than the pad pitch of the second connecting pads 30a and 30b. The first connecting pads 20a connected to the second chip 30 through the relay substrate 40 are called first connecting pads 20b and the first connecting pads 20b are formed along the side facing the second chip 30. The second connecting pads 30a connected to the first chip 20 through the relay substrate 40 are called second connecting pads 30b and the second connecting pads 30b are formed along the side facing the first chip 20. In this case, the first relay pads 40a and the second relay pads 40b are formed on the relay substrate 40 arranged between the first chip 20 and the second chip 30. The first relay pads 40a correspond to the pad pitch of the first connecting pads 20b and the second relay pads 40b correspond to the pad pitch of the second connecting pads 30b. The first relay pads 40a are formed in the side facing the first chip 20. The second relay pads 40b are formed in the side facing the second chip 30.

For example, the relay substrate 40 is a horseshoe-shaped. Hence, it is possible to connect the semiconductor chips through the relay substrate 40 even when the pad pitches of the connecting pads formed in the first chip 20 and the second chip 30 are different. The relay pads formed on the relay substrate 40 correspond to the pad pitches of the pads formed on each of the semiconductor chips, to thereby makes it possible to connect the first chip 20 and the relay substrate 40 through the bonding wires 70b and to connect the second chip 30 and the relay substrate 40 through the bonding wires 70b. Both of the two connections are substantially perpendicular to the facing side on the plane. It is also possible to suppress the degradation of the signal which is transmitted and received through the bonding wires 70b because the wiring length of the bonding wires 70b can be made substantially shortest.

In the present embodiment, the pad pitch of the first connecting pads 20b and the pad pitch of the second connecting pads 30b are different. Therefore, the number of pads of the first connecting pads 20b and the number of pads of the second connecting pads 30b, both of which are formed along the facing side, are different from each other. In such a case, it is impossible to connect all of the first connecting pads 20b with the second connecting pads 30b formed along the facing side. Therefore, in addition to the second connecting pads 30b formed along the side facing the first chip 20 on the second chip 30, a part of the second connecting pads 30a formed along the sides other than the side facing the first chip 20 is called second connecting pads 30b. For example, in the present embodiment, in addition to the second connecting pads 30b formed along the side facing the first chip 20, a part of the second connecting pads 30a formed along the sides adjacent with the facing side is called second connecting pads 30b. The relay substrate 40 in this embodiment is horseshoe-shaped, to thereby makes it possible to form the second relay pads 40b which correspond to the second connecting pads 30b formed along the sides other than the facing side on the second chip 30. Therefore, the present embodiment makes it possible to connect all of the first connecting pads 20b with the second connecting pads 30b through the relay substrate 40.

Note that the present invention is not limited to the above-described embodiment but may be changed without departing from the spirit of the present invention. For example, the first connecting pads 20a and the second connecting pads 30a are formed in two arrays in the zigzag pattern in the present embodiment. However, the first connecting pads 20a and the second connecting pads 30a may be formed in one array. Further, the first connecting pads 20a and the second connecting pads 30a may be formed in three or more arrays. Further, although the relay substrate 40 is the horseshoe-shaped in this invention, the relay substrate 40 may be L-shaped or H-shaped or the like. Moreover, although the first connecting pads 20b formed on the first chip 20 and connected to the second chip 30 are formed along the facing side, the first connecting pads 20b may be formed along the side other than the facing side. In such a case, the relay substrate 40 may be formed in H-shaped and the first relay pads 40a connected to the first connecting pads 20b may be formed.

Moreover, the first relay pads 40a and the second relay pads 40b formed on the relay substrate 40 may be formed in the pad pitch in the shortest length in advance. In this case, the connections of the bonding wires connecting the first connecting pads 20b and the first relay pads 40a and the bonding wires connecting the second connecting pads 30b and the second relay pads 40b may not be substantially perpendicular to the facing side on the plane. In such a case, the pad connected to the power supply voltage (hereinafter referred to as power supply pad) or the pad connected to the ground voltage (hereinafter referred to as ground pad) are formed between the first chip 20 and the relay substrate 40 and/or between the second chip 30 and the relay substrate 40 on the substrate 10. These power supply pads are connected to the power supply layer formed in the substrate 10, and the ground pad is connected to the ground layer formed in the substrate 10, for example. Then the first connecting pads 20b and the second connecting pads 30b can be connected to the ground pad or the power supply pad.

By having such a structure, it is possible to adjust tilt of the bonding wires 70b connecting the first connecting pads 20b and the first relay pads 40a and tilt of the bonding wires 70b connecting the second connecting pads 30b and the second relay pads 40b, to form the connection substantially perpendicular to the facing side. When the SiP is encapsulated with a resin, the bonding wires 70b can be prevented from shorting out. Moreover, the potential supplied to the first chip 20 and the second chip 30 can be made constant by connecting the first chip 20 and the second chip 30 to the power supply layer supplying the power supply voltage or to the ground layer supplying the ground voltage. Further, the first relay pads 40a which are not connected to the first connecting pads 20b and the second relay pads 40b which are not connected to the second connecting pads 30b may be connected to the power supply pad and/or the ground pad. Therefore, it is possible to make the potential of the relay substrate 40 constant.

It is apparent that the present invention is not limited to the above embodiment, but may be modified and changed without departing from the scope and spirit of the invention.

What is claimed is:

1. A semiconductor device comprising:
a first semiconductor chip having first pads arranged at first interval;
a second semiconductor chip having second pads arranged at second interval, the second interval being larger than the first interval; and
a relay substrate arranged between the first semiconductor chip and the second semiconductor chip, the relay substrate having first relay pads and second relay pads, the first relay pads arranged at first interval being formed along a side facing the first semiconductor chip and the second relay pads arranged at second interval being formed along a side facing the second semiconductor chip,
wherein the first semiconductor chip and the second semiconductor chip are connected to each other through the relay substrate.

2. The semiconductor device according to claim 1,
wherein the relay substrate is horseshoe-shaped or H-shaped.

3. The semiconductor device according to claim 2,
wherein at least one of the first relay pads and the second relay pads is also formed along a side other than the side where the first semiconductor chip and the second semiconductor chip faces to each other.

4. The semiconductor device according to claim 1,
wherein the relay substrate has a side facing side other than the side facing the first semiconductor chip on the second semiconductor chip.

5. The semiconductor device according to claim 4,
wherein the relay substrate is horseshoe-shaped or H-shaped.

6. The semiconductor device according to claim 5,
wherein at least one of the first relay pads and the second relay pads is also formed along a side other than the side where the first semiconductor chip and the second semiconductor chip faces to each other.

7. The semiconductor device according to claim 1,
wherein the relay substrate has a device reducing noise of a signal transmitted and received in the semiconductor device.

8. The semiconductor device according to claim 7,
wherein the device includes at least one of a chip capacitor, a chip resistor, and a regulator.
